(19) United States
(12) Patent Application Publication
(10) Pub. No.: US 2010/0051809 A1
(43) Pub. Date: Mar. 4, 2010

(54) Monolithic Dual Band Imager

(75) Inventors: Bora Muammer Onat, Princeton, NJ (US); Mark Allen Itzler, Princeton, NJ (US)

Correspondence Address: DEMONT & BREYER, LLC, 100 COMMONS WAY, Ste. 250, HOLMDEL, NJ, 07733, US

(73) Assignee: PRINCETON LIGHTWAVE, INC., Cranbury, NJ (US)

(21) Appl. No.: 12/551,667

(22) Filed: Sep. 1, 2009

Related U.S. Application Data
(60) Provisional application No. 61/093,593, filed on Sep. 2, 2008.

(51) Int. Cl. H01L 31/09; H01L 31/0352

(52) U.S. Cl. 250/332; 257/21; 257/E31.033

(57) ABSTRACT

An imaging sensor for imaging scenes based on both shortwave infrared and midwave infrared radiation is disclosed. The imaging sensor comprises pixels that include a photodiode that is selectively sensitive to shortwave infrared radiation based upon its bias voltage.

### CROSS REFERENCE TO RELATED APPLICATIONS

This case claims priority of U.S. Provisional Patent Application U.S. 61/093,593, which was filed on Sep. 2, 2008 (Attorney Docket: 293-018US), and which is incorporated herein by reference.

### FIELD OF THE INVENTION

The present invention relates to imaging sensors in general, and, more particularly, to infrared imaging sensors.

### BACKGROUND OF THE INVENTION

Imaging sensors that are sensitive to infrared light are useful in many applications, such as automotive, fire fighting, security, and military applications. Infrared radiation (IR) includes several ranges of wavelengths; shortwave infrared (SWIR), which includes wavelengths from approximately 900 nanometers (nm) to approximately 3000 nm; midwave infrared (MWIR), which includes wavelengths from approximately 3000 nm to approximately 5000 nm; and longwave infrared (LWIR), which includes wavelengths longer than approximately 5000 nm. In many cases, the wavelength range of the imaging sensor's sensitivity determines the types of applications for which it is particularly useful. For example, MWIR imagers are particularly useful for some military and firefighting applications, while both MWIR and SWIR imagers are used in other military, automotive, and security applications.

MWIR imagers are typically used to detect infrared light that is emitted by objects or people in a scene. Emitted infrared light is usually proportional to the temperature of an object and are well-suited for detecting warm objects in a cool environment. For example, a human will be easily detectable by an MWIR imager despite pitch black conditions since the human is a different temperature compared to a typical background. MWIR imagers are not well-suited to the identification of an object, however, as they are not capable of detecting such things as facial features or markings on clothing.

SWIR imagers, on the other hand, can be used to identify objects or people, since they are typically used to detect ambient light that is reflected off of the subjects. In fact, SWIR imagers operate much light visible light imagers. In security applications, therefore, it is possible to identify whether an approaching person is a friend or foe.

An imaging sensor that combines the capabilities of SWIR and MWIR imagers would enable both rapid detection of a subject as well as identification of the subject detected. In the prior art, such imaging system concepts have typically fused images provided by separate imaging sensors either optically or electronically. Unfortunately, such systems are bulky, expensive, and power inefficient. Their use in practical systems, therefore, has been limited—particularly where portability is desired.

Conventional SWIR imagers are based on arrays of indium-gallium-arsenide (InGaAs)-based p-i-n photodiodes. A p-i-n photodiode for infrared applications comprises epitaxially grown layers on an indium-phosphide (InP) substrate. These epitaxially grown layers typically include an InP buffer layer, an absorber layer indium-gallium-arsenide or indium-gallium-arsenide-phosphide (InGaAs or InGaAsP) and a cap layer such as InP. During processing, a dopant is diffused through a nitride pattern to form a doped region inside the wafer. The doped region is of the opposite doping than the semiconductor in which it is formed, thereby forming a p-n junction for each pixel of the photodiode array.

Conventional MWIR imagers are based on arrays of photodiodes formed using small band gap semiconductors, such as mercury-cadmium-telluride (HgCdTe) or indium antimony (InSb). Unfortunately, such photodiodes are well-known to exhibit large dark currents (i.e., noise). In order to reduce their dark currents, MWIR imagers are normally cooled to cryogenic temperatures. As a result, these imagers tend to be expensive, bulky, and extremely power inefficient.

An imaging sensor that is capable of providing images based on both SWIR and MWIR radiation, without some of the costs and disadvantages of the prior-art would, therefore, be desirable.

### SUMMARY OF THE INVENTION

The present invention enables the detection of multi-spectral radiation without some of the costs and disadvantages for doing so in the prior art. For example, embodiments of the present invention are particularly well-suited for use in infrared camera applications that require sensitivity to more than a single wavelength range.

Embodiments of the present invention comprise distinct absorber layers, wherein each absorber layer absorbs light having a wavelength within a different wavelength range. In some embodiments, a first absorber layer absorbs light having a wavelength within the SWIR wavelength range, while a second absorber layer absorbs light having a wavelength within the MWIR wavelength range. In some embodiments, a first absorber layer absorbs light having a wavelength within the range of approximately 900 nm to approximately 3000 nm, while a second absorber layer absorbs light having a wavelength within the range of approximately 3000 nm to approximately 5000 nm. In some embodiments, one of the absorber layers is a multiple quantum well.

In order to differentiate photogenerated charge carriers generated with the different absorber layers, the absorber layers are interposed by a charge blocking layer. The charge blocking capability of this charge blocking layer is turned off by applying a voltage bias to the photodiode that exceeds a threshold voltage. This threshold voltage is the voltage at which its resultant electric field extends entirely through the charge blocking layer. Once the electric field breaches the charge blocking layer, free carriers within the absorber layers are free to migrate between the layers in response to the applied electric field and are collected by the electrical contacts of the photodiode.

In some embodiments, a single photodiode is used to detect light in each of the SWIR and MWIR wavelength ranges. The photoresponsivity of the photodiode for SWIR light is toggled on and off by changing the voltage bias applied to the photodiode.

In some embodiments, two photodiodes are used to collectively define a pixel that is sensitive to each of the SWIR and MWIR wavelength ranges. Each photodiode is biased with a bias voltage that enables it to selectively detect one of the two wavelength ranges.

An embodiment of the present invention comprises: an imaging sensor comprising; a substrate; and an array of pixels, wherein the pixels and substrate are monolithically integrated, and wherein each pixel comprises; a first photodiode, wherein the first photodiode is photoresponsive for light that is characterized by a wavelength within a first range and non-photoresponsive for light that is characterized by a wavelength within a second range when the first photodiode is biased with a voltage that is less than a threshold voltage, and wherein the first photodiode is photoresponsive for light that is characterized by a wavelength within the second range when the first photodiode is biased with a voltage that is equal to or greater than the threshold voltage.

### BRIEF DESCRIPTION OF THE DRAWINGS

FIG. 1A depicts a schematic drawing of an infrared camera in accordance with an illustrative embodiment of the present invention.

FIG. 1B depicts a schematic diagram of focal plane array 106.

FIG. 2 depicts operations of a method for providing an image of a scene in accordance with the illustrative embodiment of the present invention.

FIG. 3A depicts a schematic diagram of a portion of a pixel 118 in accordance with the illustrative embodiment of the present invention.

FIG. 3B depicts a plot of an electric field developed within photodiode 300 while under a bias voltage below a first turn-on voltage.

FIG. 3C depicts a plot of an electric field developed within photodiode 300 while under a bias voltage above the first turn-on voltage.

FIG. 4 depicts a schematic diagram of an imaging sensor pixel in accordance with an alternative embodiment of the present invention.

FIG. 5 depicts operations of a method for providing an image of a scene in accordance with the alternative embodiment of the present invention.

### DETAILED DESCRIPTION

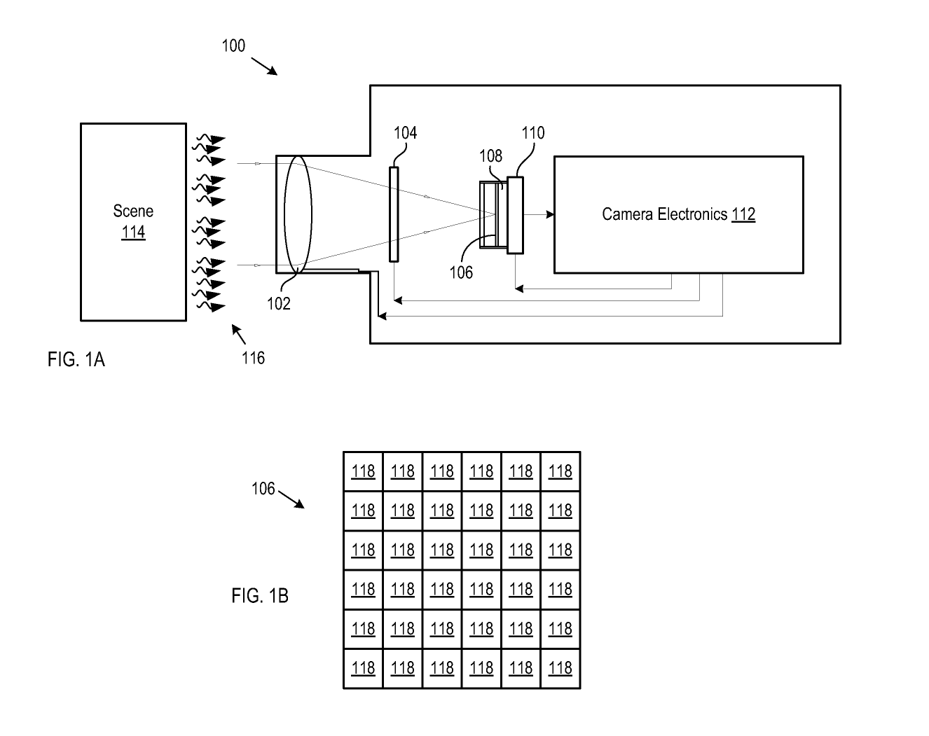

FIG. 1A depicts a schematic drawing of an infrared camera in accordance with an illustrative embodiment of the present invention. IR camera 100 comprises IR imaging optics 102, shutter 104, sensor array 106, read-out integrated circuit 108, temperature stabilizer 110, and camera electronics 112, interrelated as shown.

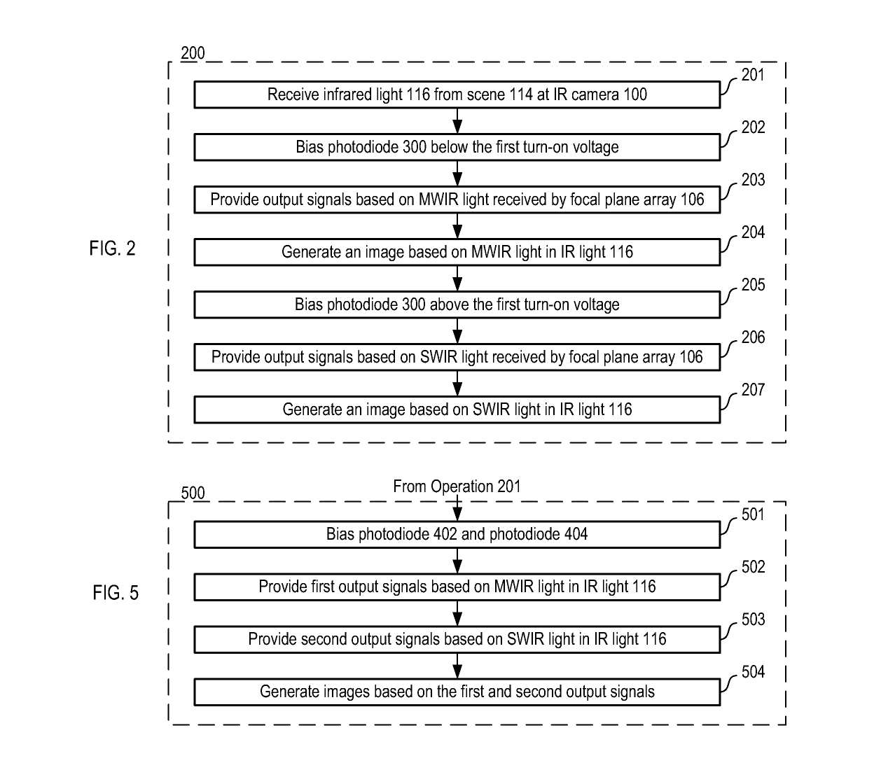

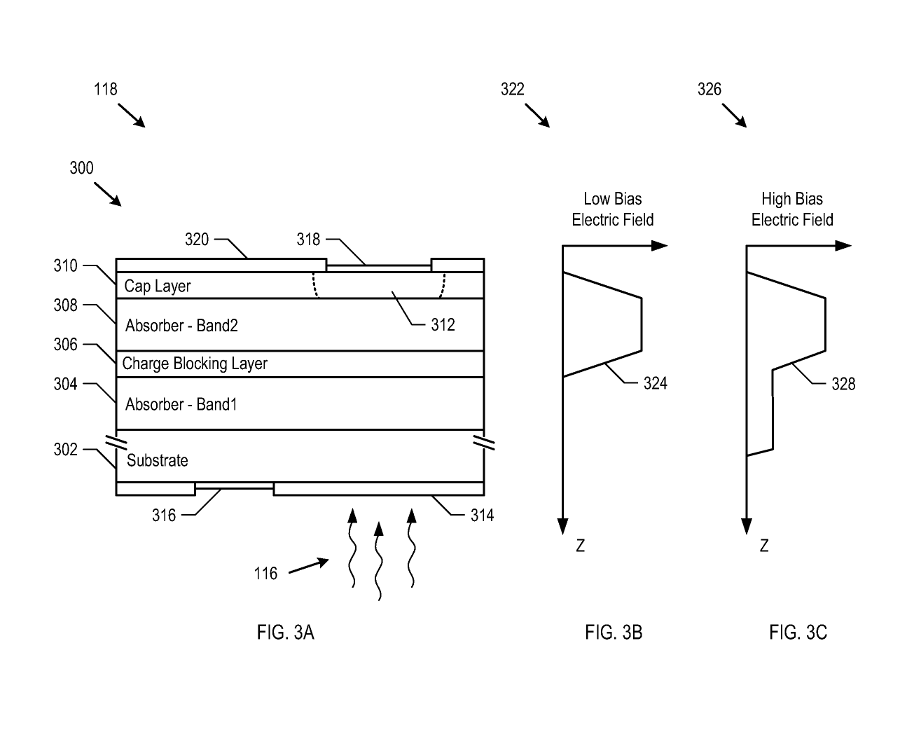

FIG. 2 depicts operations of a method for providing an image of a scene in accordance with the illustrative embodiment of the present invention. Method 200 is described herein with reference to FIGS. 3A-C and continuing reference to FIGS. 1A-B. Method 200 begins with operation 201, wherein IR light from scene 114 is received at IR camera 100.

IR imaging optics 102 include one or more lenses that receive radiant energy, such as infrared radiation. IR radiation that is received by IR imaging optics 102 is directed toward shutter 104. The shutter controls the amount of radiation that is directed toward sensor array 106. One skilled in the art will know how to make, specify, and use IR imaging optics 102 and shutter 104.

Sensor array 106 receives the radiant energy that is captured by IR imaging optics 102 and admitted by shutter 104. Sensor array 106 is located at the focal point of IR imaging optics 102 and is, therefore, properly termed a “focal plane array.” Sensor array 106 comprises an array of pixels 118 that respond to IR radiation, as depicted in FIG. 1B. Pixels 118 are described in detail below and with respect to FIGS. 3A-3C.

In response to the received radiation, each of pixels 118 provides a signal that is indicative of the IR radiation incident upon it. These signals are read by read-out integrated circuit (“ROIC”) 108, in known fashion. The ROIC generates voltage signals that are indicative of the extracted pixel-photogenerated current. ROIC 108 performs various other functions as well, including signal conditioning and amplification. Those skilled in the art will know how to use ROIC 108. In the illustrative embodiment sensor array 106 is monolithically-integrated with ROIC 108. It will be clear to those skilled in the art, however, how to make and use alternative embodiments of the present invention wherein sensor array 106 is packaged with ROIC 108 using another appropriate technology such as:

i. hybrid integration technology; or

ii. multi-chip module integration technology; or

iii. conventional integrated circuit packaging; or

iv. any combination of i, ii, and iii.

Temperature stabilizer 110 ensures that sensor array 106 is kept at a substantially constant temperature. In some embodiments, temperature stabilizer 110 is not included in IR camera 100. Camera electronics 112 includes various amplification, offset, and gain-control electronics, multiplexing and A-to-D circuitry, a camera-control microprocessor, various external control electronics, digital read-out and the like. In a nutshell, camera electronics 112 receives the voltage signals from ROIC 108 and processes the signals into an image. Camera electronics 112 also control the focus of IR imaging optics 102 and control shutter 104 and temperature stabilizer 110. Those skilled in the art will be familiar with the design and use of the various devices and circuits that compose camera electronics 112 and know how to integrate sensor array 106 therewith.

FIG. 3A depicts a schematic diagram of a portion of a pixel 118 in accordance with the illustrative embodiment of the present invention. Pixel 118 comprises photodiode 300, which is a photodiode suitable for use in a pixel of an imaging sensor that can selectively provide an image based on SWIR radiation and MWIR radiation. Photodiode 300 receives light 116 and provides an output signal based on the wavelength of the light contained in light 116. Photodiode 300 comprises substrate 302, absorber layer 304, charge blocking layer 306, absorber 308, cap layer 310, doped region 312, and contacts 316 and 318. In some embodiments, photodiode 300 provides an image based on other wavelength bands of radiation. Although the illustrative embodiment comprises a photodiode that is sensitive to the SWIR and MWIR wavelength ranges, it will be clear to one skilled in the art, after reading this specification, how to make and use alternative embodiments of the present invention that are sensitive to other wavelength ranges.

Substrate 302 is a conventional InP substrate that comprises layers of semiconductor suitable for supporting the formation of photodiode 300 (e.g., a buffer layer, etc.). In the illustrative embodiment, substrate 302 is heavily doped with an n-type dopant. In some embodiments, substrate 302 is doped with a p-type dopant. Materials suitable for use in substrate 302 include silicon, germanium, III-V semiconductors and their compounds, II-VI semiconductors and their compounds, and the like.

Absorber layer 304 is a layer of InGaAs that is epitaxially grown on substrate 302. Absorber layer 304 is physically adapted to absorb radiation in the SWIR wavelength range. Energy obtained from absorbed photons induces the generation of free charge carriers within absorber layer 304.

Absorber layer 308 is a multiple quantum well comprising a plurality of layers of semiconductor that are epitaxially grown on substrate 308. Absorber layer 308 is physically adapted to absorb radiation in the MWIR wavelength range. Absorber layer 308 is analogous to a quantum well absorber described in R. Sidhu, et al., “A long wavelength photodiode on InP using lattice-matched GaInAs-GaAsSb type II quantum wells,” IEEE Journal of Phot. Tech. Letters, Vol. 17, No. 12, pp. 2715-2717, (2005). Energy obtained from absorbed photons induces the generation of free charge carriers within absorber layer 308.

Charge blocking layer 306 is an epitaxially grown layer of charge blocking material that restricts the migration of free charge carriers between absorber layer 304 and absorber layer 308. In the illustrative embodiment, charge blocking layer 306 comprises a layer of InP that is doped with an n-type dopant. Charge blocking layer 306 is analogous to a “charge layer,” which is part of an avalanche photodiode described in M. A. Itzler, et al., “High-performance, manufacturable avalanche photodiodes for 10 Gb/s optical receivers,” Proc. of 25^{th} Optical Fiber Communications Conference (OFC 2000), Vol. 4, pp. 324-326, (2000).

Cap layer 310 is a layer of InP. In some embodiments, cap layer 310 is lightly doped with an n-type dopant; in some others, the cap layer remains undoped. In some additional embodiments, cap layer 310 is a layer of InAlAs, and in some further embodiments, cap layer 310 is a layer of InGaAsP. Cap layer 310 is suitable for operation at the SWIR and MWIR wavelength bands. Cap layer 310 comprises doped region 312. Doped region 312 is a region of cap layer 310 that is heavily doped with a p-type dopant. Doped region 312 and cap layer 310 collectively form a p-n junction and charge depletion region.

Layer 314 is disposed on the back surface of photodiode 300 (i.e., substrate 302). Layer 314 reduces or eliminates reflection of light within the desired wavelength range of operation from substrate 302.

Contact 316 is a metal contact for making electrical contact to substrate 302.

Contact 318 is a metal contact for making electrical contact to doped region 312.

Cap layer 310 is passivated with layer 320, which is a layer of silicon nitride.

At operation 202, a low bias voltage is applied between contacts 316 and 318.

FIG. 3B depicts a plot of an electric field developed within photodiode 300 while under a bias voltage below a first turn-on voltage. Plot 322 depicts electric field 324, which develops within photodiode 300 while it is biased below a voltage at which charge blocking layer 306 ceases to restrict that flow of charge between absorber layers 304 and 308 (i.e., the first turn-on voltage). The first turn-on voltage is defined as the voltage that induces an electric field large enough that the depletion region associated with doped region 312 extends through charge blocking layer 306. Under low bias (i.e., a bias below the first turn-on voltage), the depletion region can extend into, but not through, charge blocking layer 306. As a result, charge carriers liberated within absorber layer 304 by the absorption of SWIR light are restricted from passing through charge blocking layer 306. These liberated charge carriers, therefore, do not contribute to a macroscopically detectable photocurrent in response to SWIR light. In other words, under low bias, photodiode 300 is non-photoresponsive to SWIR light.

Even under low bias, however, charge carriers in absorber layer 308, which are liberated due to the absorption of MWIR light, do contribute to a detectable photocurrent. Photodiode 300, therefore, does provide an output signal in response to MWIR light. In other words, photodiode 300 is photoresponsive to MWIR light under low bias.

At operation 203, each of pixels 118 provides a first output signal based on MWIR light absorbed in absorber layer 308.

Referring now to FIGS. 1A and 1B, at operation 204, ROIC 108 receives the first output signals from pixels 118 and provides data based on the first output signals to camera electronics 112.

At operation 205, camera electronics 112 generates a first image based on the MWIR light contained in IR light 116.

At operation 205, the bias voltage between contacts 316 and 318 is increased above the first turn-on voltage.

FIG. 3C depicts a plot of an electric field developed within photodiode 300 while under a bias voltage above the first turn-on voltage. Plot 326 depicts electric field 328, which develops within photodiode 300 while it is biased above the first turn-on voltage (i.e., under high voltage bias). Under high voltage bias, the depletion region associated with doped region 312 extends through charge blocking layer 306 and electric field 324 extends into absorber layer 304. As a result, charge carriers within absorber layer 304 that are liberated by the absorption of SWIR light contribute to a detectable photocurrent. Under high voltage bias, therefore, photodiode 300 is photoresponsive to SWIR light.

At operation 206, each of pixels 118 provides a second output signal based on SWIR light absorbed in absorber layer 304.

Referring now to FIGS. 1A and 1B, at operation 206, ROIC 108 receives the second output signals from pixels 118 and provides data based on the second output signals to camera electronics 112.

At operation 207, camera electronics 112 generates a second image based on the SWIR light contained in IR light 116.

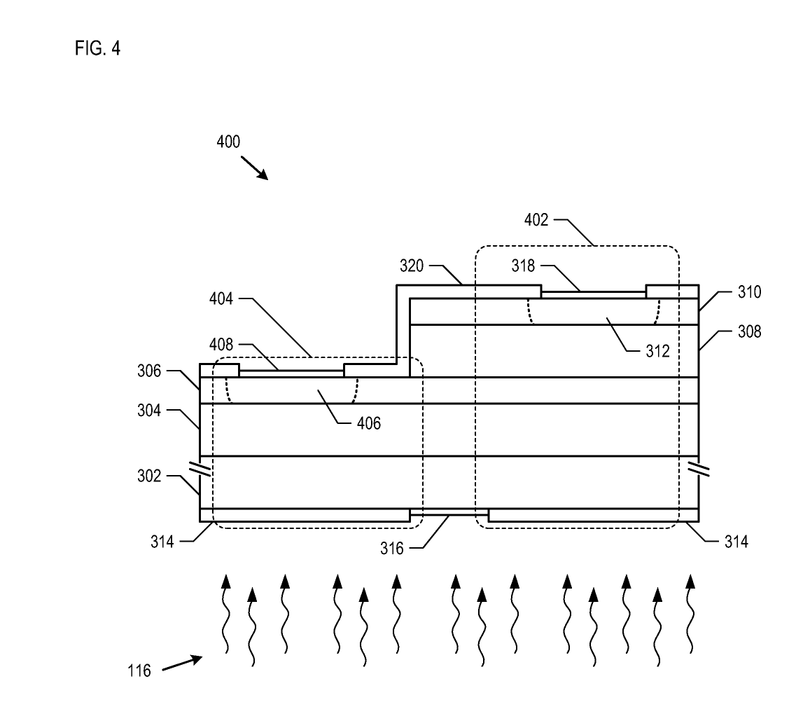

FIG. 4 depicts a schematic diagram of an imaging sensor pixel in accordance with an alternative embodiment of the present invention. Pixel 400 comprises photodiode 402 and photodiode 404.

Photodiode 402 is analogous to photodiode 300, described above and with respect to FIG. 3A.

Photodiode 404 comprises doped region 406 and contact 408. Doped region 406 is analogous to doped region 312.

FIG. 5 depicts operations of a method for providing an image of a scene in accordance with the alternative embodiment of the present invention. Method 500 begins with operation 501, wherein photodiodes 402 and 404 are each biased with a voltage below the turn-on voltage of photodiode 402.

Photodiode 402 is photoresponsive to MWIR light when biased with a voltage bias less than its turn-on voltage, as described above and with respect to photodiode 300.

When photodiode 404 is biased with a low voltage between contacts 316 and 408, an electric field extends into absorber layer 304, which enables carriers liberated by the absorption of SWIR light in absorber layer 304 to contribute to a macroscopically detectable photocurrent.

At operation 502, each of photodiodes 402 in an array of pixels 400 generates an output signal based on MWIR light in IR light 116 and provides it to an ROIC (not shown). In similar fashion, at operation 503, each of photodiodes 404 in the array of pixels 400 generates a second output signal based on SWIR light in IR light 116. The ROIC provides conditioned signals to camera electronics 112.

At operation 504, camera electronics 112 develops an MWIR image based on the first output signals and a SWIR image based on the second output signals.

It is to be understood that the disclosure teaches just one example of the illustrative embodiment and that many variations of the invention can easily be devised by those skilled in the art after reading this disclosure and that the scope of the present invention is to be determined by the following claims.

What is claimed is:

1. An imaging sensor comprising:
a substrate; and
an array of pixels, wherein the pixels and substrate are monolithically integrated, and wherein each pixel comprises;
a first photodiode, wherein the first photodiode is photoresponsive for light that is characterized by a wavelength within a first range and non-photoresponsive for light that is characterized by a wavelength within a second range when the first photodiode is biased with a voltage that is less than a threshold voltage, and wherein the first photodiode is photoresponsive for light that is characterized by a wavelength within the second range when the first photodiode is biased with a voltage that is equal to or greater than the threshold voltage.

2. The imaging sensor of claim 1 wherein each pixel further comprises:
a second photodiode that is photoresponsive for light that is characterized by a wavelength within the second range when the second photodiode is biased with a voltage that is less than a threshold voltage.

3. The imaging sensor of claim 1 wherein the first range is the midwave infrared wavelength range.

4. The imaging sensor of claim 1 wherein the first range comprises wavelengths within the range of approximately 3000 nm to approximately 5000 nm.

5. The imaging sensor of claim 1 wherein the second range is the shortwave infrared wavelength range.

6. The imaging sensor of claim 1 wherein the second range comprises wavelengths within the range of approximately 900 nm to approximately 3000 nm.

7. The imaging sensor of claim 1 wherein the first photodiode comprises:
a first absorption layer, wherein the first absorption layer is absorptive for light that is characterized by a wavelength within the second range and non-absorptive for light that is characterized by a wavelength within the first range;
a second absorption layer, wherein the second absorption layer is absorptive for light that is characterized by a wavelength within the first range;
a first doped region formed in the second absorption layer, wherein the first doped region and the second absorption layer form a first p-n junction; and
a charge blocking layer, wherein the charge blocking layer interposes the first absorption layer and the second absorption layer.

8. The imaging sensor of claim 7 wherein the second absorption layer comprises a multiple quantum well.

9. The imaging sensor of claim 7 further comprising a second doped region formed in the second absorption layer, wherein the second doped region and the first absorption layer form a second p-n junction.

10. The imaging sensor of claim 1 further comprising electrical circuitry, wherein the electrical circuitry differentiates between a photoresponse of the first photodiode due to light characterized by a wavelength within the first range and a first photoresponse of the first photodiode due to light characterized by a wavelength within the second range.

11. A pixel comprising a first photodiode, wherein the first photodiode comprises:
(1) a substrate;
(2) a first contact, wherein the first contact and the substrate are electrically connected; and
(3) a first photodiode, wherein the first photodiode comprises;
a first absorption layer disposed on the substrate, wherein the first absorption layer generates charge carriers in response to light characterized by a wavelength that is within a first range;
a second absorption layer disposed on the first absorption layer, wherein the second absorption layer generates charge carriers in response to light characterized by a wavelength that is within a second range;
a first doped region formed in the second absorption layer, wherein the first doped region and the second absorption layer form a first p-n junction;
a charge blocking layer, wherein the charge blocking layer interposes the first absorption layer and the second absorption layer; and
a second contact, wherein the second contact and the first doped region are electrically connected;
wherein the first photodiode provides a first photocurrent based on the absorption of light by only the second absorption layer when a first voltage is less than a threshold voltage, wherein the first voltage is between the first contact and the second contact; and
wherein the first photodiode provides a second photocurrent based on the absorption of light by the first absorption layer when the first voltage is equal to or greater than the threshold voltage.

12. The pixel of claim 11 further comprising:
(4) a second photodiode, wherein the second photodiode comprises;
the first absorbing layer;
a second doped region, wherein the second doped region and the first absorbing layer form a second p-n junction; and
a third contact, wherein the third contact and the second doped region are electrically connected;
wherein the second photodiode provides a third photocurrent based on the absorption of light by the first absorbing layer when a second voltage is less than a threshold voltage, wherein the second voltage is between the first contact and the third contact.

13. The pixel of claim 11 wherein the second absorption layer comprises a multiple-quantum well.

14. The pixel of claim 11 further comprising a processor:
wherein the processor provides the first voltage between the first contact and the second contact;
wherein the processor receives the photocurrent from the first photodiode; and
wherein the processor provides an output signal that is based on at least one of the first photocurrent and second photocurrent and the first voltage.

15. The apparatus of claim 11 wherein the first range comprises wavelengths within the range of approximately 3000 nm to approximately 5000 nm.

16. The apparatus of claim 11 wherein the second range comprises wavelengths within the range of approximately 900 nm to approximately 3000 nm.

17. An imaging sensor, wherein the imaging sensor comprises a plurality of pixels, and wherein each pixel comprises a first photodiode that comprises:
a first absorption layer having a first thickness, wherein the first absorption layer generates charge carriers in response to absorption of light having a wavelength within a first range;
a second absorption layer having a second thickness, wherein the second absorption layer generates charge carriers in response to absorption of light having a wavelength within a second range;
a first doped region, wherein the first doped region and the first absorption layer form a first charge depletion region having a first depletion region depth; and
a charge blocking layer having a third thickness, wherein the charge blocking layer interposes the first absorption layer and the second absorption layer;
wherein the movement of charge carriers between the first absorption layer and the second absorption layer is restricted when the first depletion region depth is less than the first thickness; and
wherein the movement of charge carriers between the first absorption layer and the second absorption layer is enabled when the first depletion region depth is greater than the sum of the first thickness and the third thickness.

18. The image sensor of claim 17 wherein the first absorption layer comprises a multiple quantum well.

19. The image sensor of claim 17 further comprising a processor, wherein the processor controls the first depletion region depth.

20. The image sensor of claim 17 wherein each pixel further comprises a second photodiode that comprises:
the second absorption layer; and
a second doped region, wherein the second doped region and the second absorption layer form a second charge depletion region having a second depletion depth.

21. The image sensor of claim 20 wherein each pixel provides an output signal that is based on at least one of a first photocurrent provided by the first photodiode and a second photocurrent provided by the second photodiode.

22. The image sensor of claim 21 further comprising a processor, wherein the processor controls the first depletion region depth for each pixel, and wherein the first processor generates image data based on the output signal provided by each pixel of the plurality of pixels.

23. The image sensor of claim 17 wherein the first photodiode provides a first photocurrent that is based on the intensity of received light having a wavelength within the first range, and wherein the first photodiode provides a second photocurrent that is based on the intensity of received light having a wavelength within the second range.

24. A method comprising:
receiving an optical image at an image sensor comprising a plurality of pixels, wherein each of the plurality of pixels comprises a first photodiode;
providing a first bias voltage to each first photodiode, wherein the first bias voltage enables the first photodiode to provide a photocurrent based on light having a wavelength within a first range and disables the first photodiode from providing a photocurrent based on light having a wavelength within a second range; and
generating a first output for each of the plurality of pixels, wherein each first output is based on the intensity of light received by the first photodiode that has a wavelength within the first range.

25. The method of claim 24 further comprising:
changing the first bias voltage to each first photodiode to enable the first photodiode to provide a photocurrent based on light having a wavelength within the second range; and
generating a second output for each of the plurality of pixels, wherein each second output is based on the intensity of light received by the first photodiode that has a wavelength within the second range.

26. The method of claim 25 further comprising:
generating a first image that is based on the first output of each of the plurality of pixels; and
generating a second image that is based on the second output of each of the plurality of pixels.

27. The method of claim 24 further comprising generating a first image that is based on the first output of each of the plurality of pixels.

28. The method of claim 24 further comprising providing a second bias voltage to a second photodiode included in each pixel, wherein the second bias voltage enables the second photodiode to provide a photocurrent that is based on light having a wavelength within the second range;
generating a second output for each of the plurality of pixels, wherein each second output is based on the intensity of light received by the second photodiode that has a wavelength within the second range; and
generating a second image that is based on the second output of each of the plurality of pixels.
